(19) United States
(12) Patent Application Publication
(10) Pub. No.: US 2010/0163108 A1
(43) Pub. Date: Jul. 1, 2010

(54) ELECTROCHEMICALLY ACTIVE ORGANIC THIN FILM, METHOD FOR PRODUCING THE SAME, AND DEVICE USING THE SAME

(76) Inventors: Takeshi Bessho, Aichi (JP); Hiroyuki Sugimura, Kyoto (JP); Kuniaki Murase, Kyoto (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/438,187

(22) PCT Filed: Aug. 27, 2007
(86) PCT No.: PCT/JP2007/067087

§ 371 Date: Feb. 20, 2009

(30) Foreign Application Priority Data
Aug. 28, 2006 (JP) 2006-230867

(51) Int. Cl. H01L 31/0256; B32B 9/04; B05D 5/12; B32B 37/00; G01N 27/26; H01L 51/10; H01L 51/40

(52) U.S. Cl. 136/263; 428/447; 427/126.1; 156/60; 204/400; 257/40; 438/99; 257/E51.023; 977/774; 977/932

(57) ABSTRACT

This invention provides an electrochemically active organic thin film capable of repeating reversible oxidation/reduction a number of times. Further, the invention provides a novel approach to so-called “molecular nanoelectronics” utilizing organic molecules as operating units, with the use of such organic thin film. Such electrochemically active organic thin film comprises a substrate, an organic molecular film comprising organic molecules having terminal amino groups chemically fixed on the surface of the substrate, and metal atoms or metal ions coordinately hound to the amino groups.

### TECHNICAL FIELD

The present invention relates to an electrochemically active organic thin film capable of repeating reversible oxidation/reduction a number of times, a method for producing the same, and several devices using the same.

### BACKGROUND ART

Advancement in miniaturization of semiconductor integrated circuits (ICs) is continual. In 2005, mass-production of super-integrated circuits having a minimum linewidth of 65 nm became possible. The design rule with a minimum linewidth of 22 nm is the goal to be reached within 10 years. Further, the processing accuracy at the atomic and molecular levels, such as a process linewidth of 10 nm or smaller, will be required in the near future. However, whether electronic devices of such single-nanotechnology era can be constructed with the use of existing electronic materials, semiconductors, metals, or dielectric substances is a serious issue of concern. Accordingly, a breakthrough in material engineering has been desired.

As a resolution for the limited miniaturization of semiconductor ICs, so-called “molecular nanoelectronics” utilizing organic molecules as operating units has been proposed. As an ultimate means for miniaturization of electronic ICs to the molecular level, such molecular nanoelectronics is a very appealing concept, and it has drawn attention from many researchers.

After 30 years from the first proposal, however, construction of electronic circuits consisting of organic molecules still remains difficult. Although such technique is making steady progress, a chance for a molecular semiconductor or the like having a response speed comparable to that of a highly conductive molecular wire, silicon, or compound semiconductor that can replace a metal wire to be put to practical use in the near future is very low.

As a realistic application of organic molecules as elements of electronic integrated circuits, appropriate use of advantages of an organic molecular material in combination with those of a semiconductor material is effective.

An advantage of an organic molecular material, for example, is availability of a so-called “self-organization/self-assembly process” that makes use of interactions among organic molecules to assemble molecules. Self-assembly enables the preparation of ultrathin films having no defects and having a thickness of 1 to 2 nm, quantum nanodot arrays, or the like. When a solid substrate is coated with such organic self-assembled monolayer, the surface of the substrate is densely coated with given well-oriented organic molecules. This can cause remarkable changes in various surface properties of the substrate.

The document, Surface and Interface Analysis 2002, 34, 550-554, describes the formation of a self-assembled monolayer (SAM).

A self-organization/self-assembly phenomenon such that minimal elements, such as atoms, molecules, and fine particles, spontaneously assemble and regularly align plays a key role in a bottom-up material nanotechnology whereby assembling minimal elements to construct materials. An example of material processing that utilizes self-assembly is the monolayer film/multilayer film formation caused by self-assembly of organic molecules. Such processing has drawn attention as a process of preparing a ultrathin film with a film thickness/layer thickness at the molecular levels.

It has been heretofore known that a given organic molecular species exhibits specific adsorption phenomenon on the solid surface. In line with the advancement in surface analytical techniques of recent years, it was demonstrated that interactions among adsorbed molecules result in spontaneous assembly, the adsorbed molecules are densely assembled, and a layer of well-oriented molecules may then be occasionally formed during the process of adsorption. When a layer of adsorbed molecules is a monolayer, i.e., when a monolayer is formed, such monolayer is referred to as a self-assembled monolayer (SAM). In Japanese, such layer is often referred to as a “self-assembled monolayer (SAM)” or a “self-organized monolayer.” From the viewpoint of the molecular alignment of the complete monolayer, the expression “self-organization” is equivalent to the term “self-assembly,” when a process of molecular assembly is focused.

### DISCLOSURE OF THE INVENTION

The present invention provides an electrochemically active organic thin film capable of repeating reversible oxidation/reduction a number of times. Further, the present invention provides a novel approach to so-called “molecular nanoelectronics” utilizing organic molecules as operating units, with the use of such organic thin film.

The present inventors discovered that an organic thin film comprising a substrate, organic molecules having given terminal functional groups fixed on the surface of the substrate, and complexes of metal atoms or metal ions with such terminal functional groups has electrochemical activity, which enables repetition of reversible oxidation/reduction a number of times. This has led to the completion of the present invention.

Specifically, the first aspect of the present invention concerns an electrochemically active organic thin film that comprises a substrate, an organic molecular film comprising organic molecules having terminal amino groups chemically fixed on the surface of the substrate, and metal atoms or metal ions coordinately bound to the amino groups. The term “electrochemically active (or electrochemical activity)” used herein refers to the capacity for repeating reversible oxidation/reduction a number of times. The organic thin film of the present invention undergoes oxidation/reduction by an increase or decrease in electric charges upon transmission/reception of electrons of the central metal of the complex. Since this oxidation/reduction reaction is reversible, various devices utilizing the organic thin film of the present invention as an operating unit can be prepared.

The organic molecular film of the present invention is preferably a monolayer, and particularly preferably a self-assembled monolayer (SAM). Self-assembly enables the preparation of a ultrathin film having no defects and having a thickness of 1 to 2 nm.

As organic molecules having terminal amino functional groups that constitute an organic thin film, a wide variety of compounds can be used as long as such compounds can chemically bind to various substrates. Among them, aminosilane compounds are preferable, and aminosilane compounds having 2 amine nitrogen atoms in their molecules are particularly preferable. A single transition metal complex is formed by a total of 4 amine nitrogen atoms of adjacent 2 molecules.

Specific examples of preferable aminosilane compounds include aminoethylaminopropyltrimethoxysilane and aminoethylaminopropyltriethoxysilane.

As a substrate on which the organic thin film of the present invention is formed, a wide variety of substrates that can react with and chemically bind to organic molecules having terminal amino functional groups on the substrate surface can be used. For example, a member selected from among a metal oxide substrate, a metal substrate coated with an oxide film, a metal substrate, and a semiconductor substrate is preferable. Among them, a silicon substrate, a titanium oxide substrate, a tin oxide substrate, and a indium/tin oxide substrate are preferable from the viewpoint of application thereof to various electronic devices.

In the organic thin film of the present invention, various transition metal ions are preferably used as metal atoms or metal ions that serve as central metals of the complex. A particularly preferable example thereof is a ruthenium ion.

The organic thin film of the present invention may be a monolayer film or a multilayer film that sandwiches a central metal that forms a complex. Specifically, the present invention also includes an organic multilayer thin film comprising: a substrate; a layer of organic molecules having terminal amino functional groups chemically fixed on the surface of the substrate; metal atoms or metal ions coordinately bound to the terminal amino functional groups as ligands to form complexes; and a layer of organic molecules having terminal amino functional groups as ligands coordinately bound to the metal atoms or metal ions.

The second aspect of the present invention concerns a method for producing the electrochemically active organic thin film. This method comprises at least a step of chemically fixing organic molecules having terminal amino functional groups on a substrate surface and a step of coordinating metal atoms or metal ions to the terminal amino functional groups as ligands to form complexes.

As described above, the step of chemically fixing organic molecules having terminal amino functional groups on the substrate surface is preferably a step of forming a self-assembled monolayer (SAM). As the step of forming a self-assembled monolayer (SAM) via silane coupling, a method wherein a hydroxyl group is allowed to react with organic silane on the surface of the oxide is available. This method is applicable to the present invention. In the step of forming a self-assembled monolayer (SAM) via silane coupling, however, it is necessary to coat a silicon substrate with an oxide film with a thickness of at least several nm. Accordingly, electronic functions of the organic thin film of the present invention can be utilized only when an insulator is inserted between the self-assembled monolayer (SAM) and the silicon substrate.

A method for forming a self-assembled monolayer (SAM) directly on the surface of a silicon substrate without an oxide film involves the introduction of a radical reaction initiator, heating, light application, and the like. Further, hydrogen atoms are removed from the hydrogen-terminated silicon surface to generate silicon radicals, and the generated silicon radicals may be reacted with the organic molecules having terminal amino functional groups.

Further, a step of forming a self-assembled monolayer (SAM) is particularly preferably carried out by a gas-phase process wherein organic molecules having terminal amino functional groups are directly vapor-deposited on the surface of a substrate such as a silicon substrate, from the viewpoint of a dry process and an adequate apparatus size.

As described above, organic molecules having terminal amino functional groups are preferably aminosilane compounds. More specifically, aminosilane compounds are preferably aminoethylaminopropyltrimethoxysilane or aminoethylaminopropyltriethoxysilane. A substrate is preferably a member selected from among a metal oxide substrate, a metal substrate coated with an oxide film, a metal substrate, and a semiconductor substrate. A silicon substrate, a titanium oxide substrate, a tin oxide substrate, and a indium/tin oxide substrate are particularly preferable. A metal atom or metal ion is preferably a transition metal ion, and a ruthenium ion is particularly preferable.

The method for producing the organic thin film of the present invention further comprises a step of laminating a ligand film comprising terminal amino functional groups of organic molecules on the metal atom or metal ion.

The third aspect of the present invention concerns various devices utilizing the above-mentioned electrochemically active organic thin film as operating units. Specific examples are the following (1) to (4):

(1) a molecular memory device utilizing the oxidation/reduction capacity of the organic thin film as a means for retaining and releasing electric charges;

(2) a molecular transistor device utilizing the oxidation/reduction capacity of the organic thin film as a means for regulating electron migration between a source charge and a drain electrode;

(3) an electrochemical sensor utilizing the oxidation/reduction capacity of the organic thin film as a means for detecting electron migration between an electrode and a substance to be detected; and

(4) a dye-sensitized solar cell utilizing the oxidation/reduction capacity of the organic thin film as a dye.

### Effects of the Invention

The present invention provides an excellent electrochemically active organic thin film comprising a substrate, organic molecules having terminal amino functional groups chemically bound to the surface thereof, and metal atoms or metal ions coordinately bound to the terminal amino functional groups as ligands to form complexes. The term “electrochemically active (or electrochemical activity)” used herein refers to the capacity for repeating reversible oxidation/reduction a number of times. The organic thin film of the present invention undergoes oxidation/reduction by an increase or decrease in electric charges upon transmission/reception of electrons of the central metal of the complex. Since this oxidation/reduction reaction is reversible, various devices utilizing organic molecules as operating units can be prepared using the organic thin film of the present invention.

### BRIEF DESCRIPTION OF THE DRAWINGS

FIG. 1A-1C is a conceptual diagram showing a process of forming a self-assembled monolayer (SAM) having ligand terminuses and a process of coordinating metal ions. FIG. 1A shows a process of forming SAM having ligand terminuses on a substrate; FIG. 1B shows a process of coordinating metal ions to ligand terminuses; and FIG. 1C shows a process of forming SAM having ligand terminuses on metal ions coordinately bound to the ligand terminuses to form a multilayer film.

FIG. 2A-2C shows an example of adsorption of ruthenium ions onto an aminosilane monolayer. FIG. 2A shows a chemical formula representing N-(2-aminoethyl)-3-amino-propyltrimethoxysilane (AEAPS) molecules; FIG. 2B shows a configuration of a monolayer of AEAPS molecules on a silicon substrate; and FIG. 2C shows a metal complex formed by coordinating ruthenium ions to the monolayer of AEAPS molecules.

FIG. 3 shows the N1s spectra of the surfaces of the samples treated with AEAPS for 0.5, 1, and 5 hours.

FIG. 4 shows the nitrogen concentration on the surface of the AEAPS-treated sample.

FIG. 5 shows the results of measuring the film thickness of the surface adsorptive layer of the AEAPS-treated sample.

FIG. 6 shows the photoelectron spectroscopy spectra of the substrate treated with ruthenium chloride.

FIG. 7 shows the cyclic voltammogram (CV) for electrochemical responses of the AEAPS monolayer samples having no ruthenium adsorbed thereon.

FIG. 8 shows the cyclic voltammogram (CV) for electrochemical responses of the AEAPS monolayer samples having ruthenium adsorbed thereon.

FIG. 9A-9C shows an example of a structure of a device when oxidation/reduction (redox) performance of the organic molecules of the present invention are utilized for a memory device. FIG. 9A shows an example of a structure of a redox-type molecular memory device; FIG. 9B shows charge accumulation on a redox-type molecular memory device; and FIG. 9C shows the performance of FET after charge accumulation.

FIG. 10 shows an application example of redox performance of the organic thin film of the present invention to a molecular transistor device utilized as a means for regulating electron migration between a source charge and a drain electrode.

FIG. 11 shows an application example of redox performance of the organic thin film of the present invention to an electrochemical sensor utilized as a means for detecting electron migration between an electrode and a substance to be detected.

### PREFERRED EMBODIMENTS OF THE INVENTION

When the hydrogen-terminated silicon surface is subjected to thermal excitation/photoexcitation, hydrogen atoms on the surface are removed, and silicon radicals are generated. By the reaction between the silicon radicals and organic molecules, silicon radicals are conjugated to organic molecules, so that a monolayer can be formed. In the case of the reaction between the silicon radicals and unsaturated hydrocarbons, alcohol molecules, or aldehyde molecules, for example, organic molecules are fixed on a silicon substrate via a Si—C bond, and a monolayer is formed. The reaction temperature is between 100° C. and 200° C.; however, it is highly unlikely that a Si—H bond is cleaved at such low temperature and that hydrogen atoms are removed. Accordingly, removal of hydrogen atoms is considered to take place at sites where hydrogen atoms are easily removed for some reasons, and the reaction is considered to advance because of the chain reaction.

A method wherein metal complex molecules are fixed on a silicon substrate surface by thermal excitation of hydrogen-terminated silicon is effective, although this method suffers from several drawbacks. Specific examples of such drawbacks include: a metal ion-ligand combination that is unstable at high temperature decomposes during the process of coating; and addition of reactive functional groups to metal complex molecules is required so as to fix the organic metal complex molecules to the substrate. In order to design a material with a higher degree of freedom, it is desirable to develop a technique for fixing electrochemically active molecules via the other approach.

According to the present invention, a monolayer comprising terminal functional groups as ligands is provided on the substrate in advance, the functional ligand groups are then coordinately bound to metal ions to form complexes, and electrochemical activity is imparted thereto. This technique is advantageous in that selection of a central metal enables regulation of redox potentials and expansion by the formation of a multilayer film.

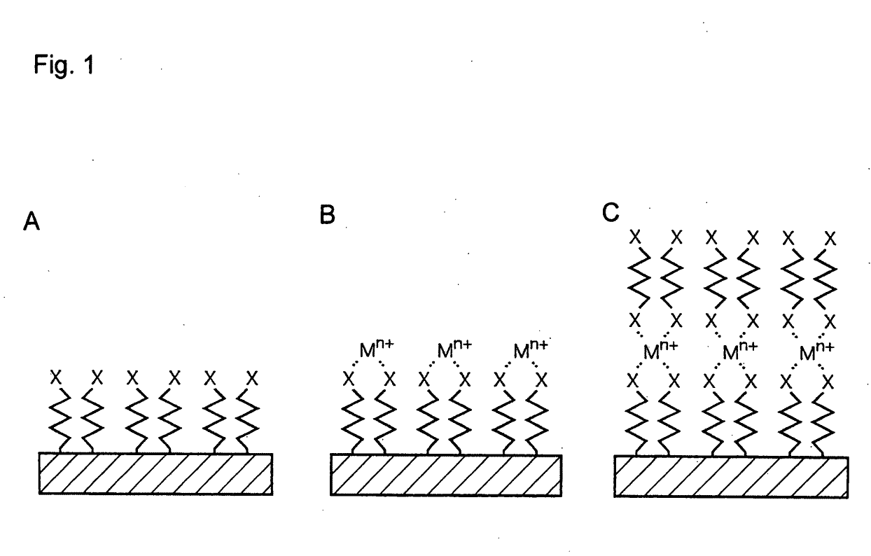

FIG. 1A-1C is a conceptual diagram showing a process of forming a self-assembled monolayer (SAM) having ligand terminuses and a process of coordinating metal ions. FIG. 1A shows a process of forming SAM having ligand terminuses on a substrate; FIG. 1B shows a process of coordinating metal ions to ligand terminuses; and FIG. 1C shows a process of forming SAM having ligand terminuses on metal ions coordinately bound to the ligand terminuses to form a multilayer film.

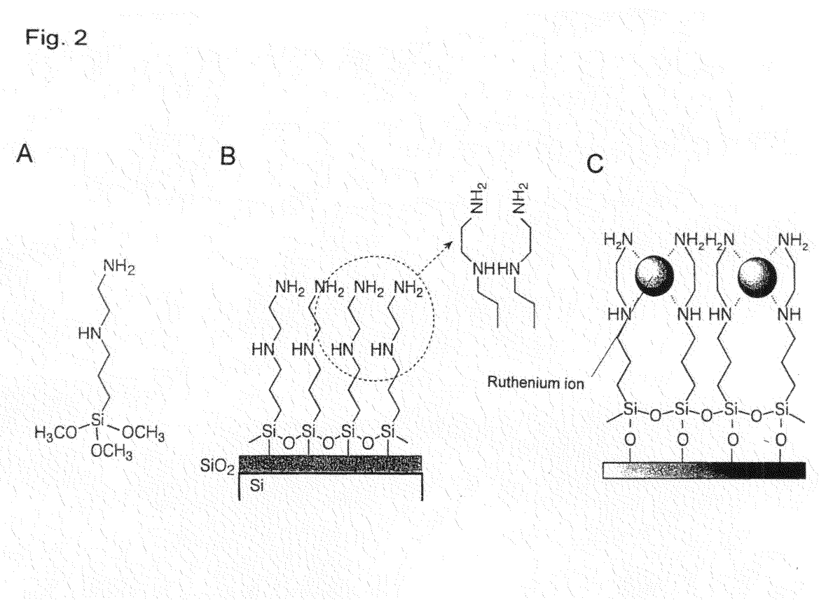

FIG. 2A-2C shows an example of adsorption of ruthenium ions onto an aminosilane monolayer. FIG. 2A shows a chemical formula representing N-(2-aminoethyl)-3-amino-propyltrimethoxysilane (AEAPS) molecules; FIG. 2B shows a configuration of a monolayer of AEAPS molecules on a silicon substrate; and FIG. 2C shows a metal complex formed by coordinating ruthenium ions to the monolayer of AEAPS molecules.

A monolayer of aminosilane molecules comprising amine nitrogen atoms that function as ligands is formed, and transition metal ions that form a complex with the aminosilane monolayer is adequately selected. Thus, a function of performing reversible electrochemical response can be exhibited. In the procedure shown in FIG. 2A to 2C, N-(2-aminoethyl)-3-amino-propyltrimethoxysilane (AEAPS) having 2 amine nitrogen atoms as aminosilane molecules is used, a monolayer is formed by a gas-phase process, and a complex of the resulting monolayer and ruthenium is formed. AEAPS was used because a chelating complex could be formed between 2 AEAPS molecules and metal ions to incorporate metal ions more steadily, as shown in FIG. 2C. Although reduced ruthenium is not charged, it becomes a positively charged ruthenium oxide upon electron release. In addition, such positively charged ruthenium oxide can receive electrons and return to the form of non-charged reduced ruthenium, and such reactions are reversible.

A ruthenium-amino complex is used as a dye of a dye-sensitized solar cell, and such complex can function as an optically functional material as well as an electochemical material.

Hereafter, examples of the present invention are provided.

### [Preparation of Electrochemically Active Organic Thin Film]

### (Specification of a Silicon Substrate)

A n-Si (111) and As-doped (concentration≅4×10¹⁸ cm³) silicon substrate with a resistivity of 0.001˜0.004 Ω·cm was used to form a surface-oxidized film having a thickness of a little smaller than 2 nm via photooxidation.

### (Formation of AEAPS Monolayer)

In a nitrogen-substituted globe compartment (room temperature, relative humidity; 13%), 0.1 cm³ of AEAPS was diluted with 0.7 cm³ of toluene, and the resulting solution was introduced into a glass vial. The glass vial and the silicon substrate were sealed in a capped PFA (Teflon®) container (volume: 120 cm³), and the sealed container was kept in an electric furnace, which was set at 100° C., for a given period of time. After the film was formed, the film was successively subjected to ultrasonic cleaning for 20 minutes with toluene, ethanol, an aqueous solution of 1 mM sodium hydroxide, and 1 mM nitric acid, respectively. The film was rinsed with ultrapure water in the end.

### (Formation of Ruthenium Complex)

An aqueous solution containing 1 mM of ruthenium chloride (III) and 1 mM of hydrochloric acid was prepared, and a substrate coated with the AEAPS monolayer was soaked therein for 1 hour. After the reaction, the substrate was ultrasonically cleaned with ultrapure water for 20 minutes.

### [Results and Examination of Gas Phase Crystal Growth of AEAPS Monolayer]

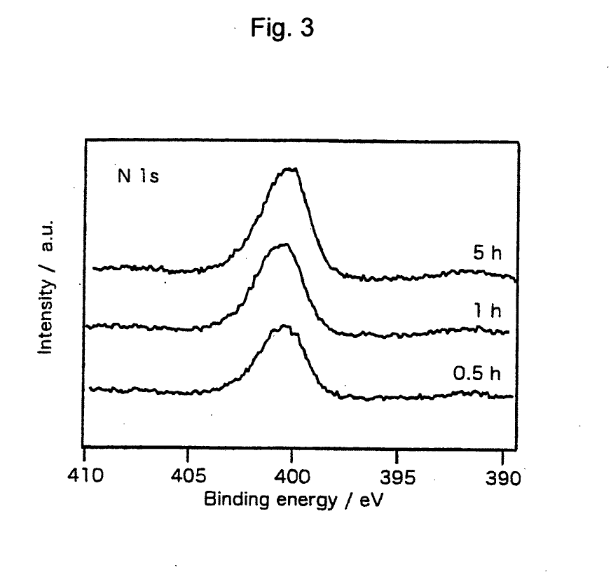

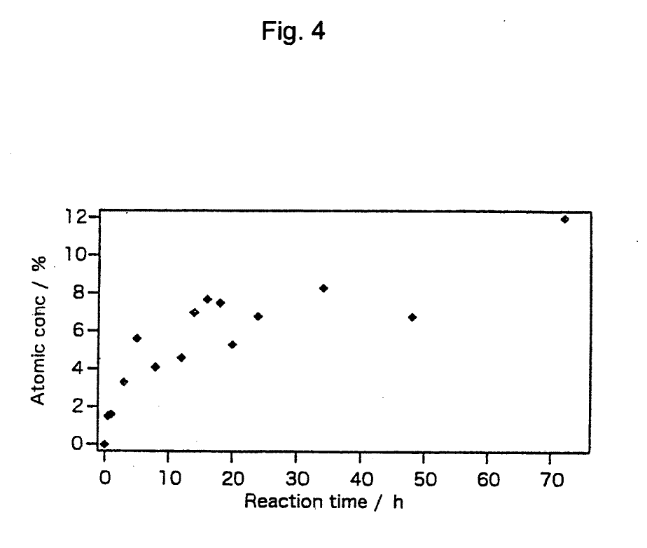

FIG. 3 shows the N1s spectra of the surfaces of the samples treated with AEAPS for 0.5, 1, and 5 hours. As is apparent from the figure, a signal emitted from a nitrogen atom is clearly detected, and AEAPS molecules are adsorbed on the substrate. FIG. 4 shows the nitrogen concentration on the surface of the AEAPS-treated sample. The rate of the nitrogen concentration increased on the surface gradually becomes mild as the processing duration is prolonged, compared with the rate of increase for the first several hours. The monolayer may be formed within several hours, and excessive adsorption of AEAPS molecules may take place thereafter. Thus, the growth process was examined in more detail by measuring a film thickness using an ellipsometer.

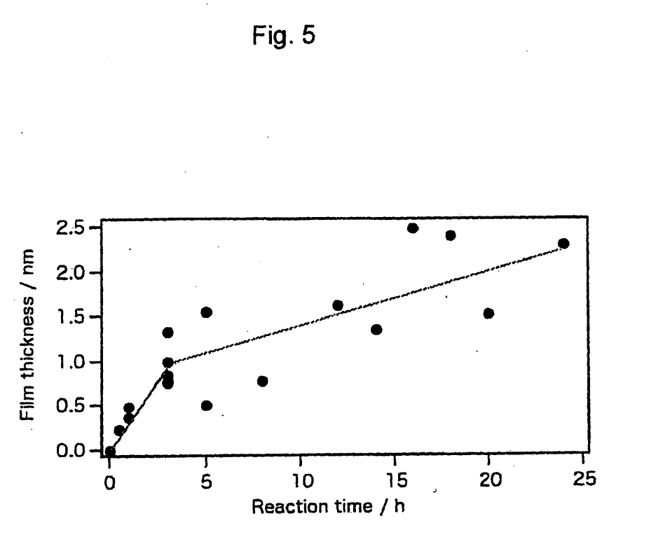

FIG. 5 shows the results of measuring the film thickness of the adsorptive surface layer of the AEAPS-treated sample. As is apparent from the figure, the rate of a film thickness increase becomes smaller 3 hours after the treatment and thereafter, compared with the rate thereof up to 3 hours after the treatment. This indicates that a growth regime of a film becomes different at the time point 3 hours after the treatment. Since the molecular length of AEAPS is 0.95 nm, a thin film comparable to a monolayer is formed 3 hours after the initiation of the reaction at which a film having a thickness of about 0.9 nm is obtained. If the duration of treatment exceeds 3 hours, AEAPS molecules may be excessively adsorbed on the monolayer. It can be accordingly concluded that reaction conditions of 100° C. for 3 hours are sufficient to obtain a film of AEAPS molecules comparable to a monolayer by a gas-phase process.

### [Results and Examination of Adsorption of Ruthenium on AEAPS Monolayer]

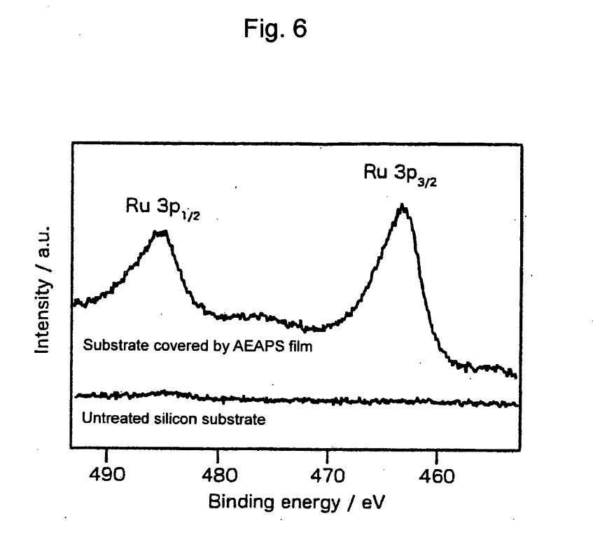

Ruthenium ions were adsorbed on a sample coated with the AEAPS monolayer prepared via the reaction at 100° C. for 3 hours. In order to inspect whether ruthenium ions adsorb on the sample because of the presence of AEAPS molecules, the photoelectron spectroscopy spectrum of the AEAPS monolayer-coated substrate and that of a ruthenium-chloride-treated silicon substrate, which was not coated with the AEAPS monolayer, were assayed. FIG. 6 shows the photoelectron spectroscopy spectra of the substrate treated with ruthenium chloride. When the substrate was not coated with the AEAPS monolayer, ruthenium did not adsorb thereon at all. This indicates that ruthenium ions were incorporated into the monolayer by the interaction between the amino group and ruthenium. At the same time, substantially no chlorine was observed on the surface of the sample that had been ultrasonically cleaned. Thus, only ruthenium ions were found to be adsorbed instead of ruthenium chloride. It can be accordingly deduced that ruthenium ions were fixed via coordination bonds of ruthenium ions to amino groups.

### [Electrochemical Activity of Organic Thin Film]

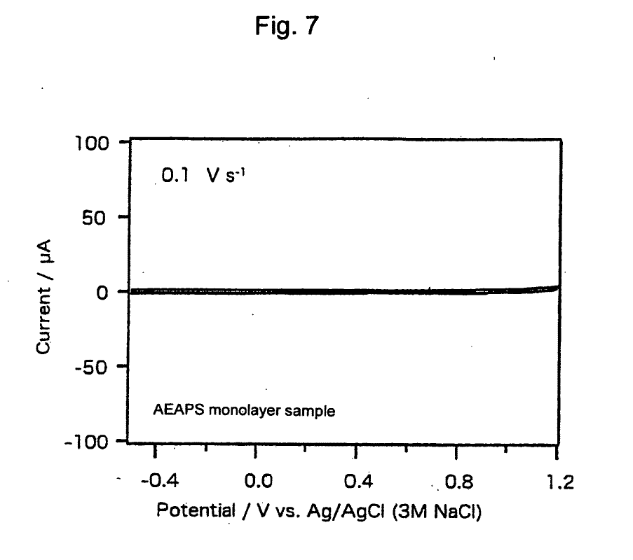

FIG. 7 shows the cyclic voltammogram (CV) of the AEAPS monolayer samples having no ruthenium adsorbed thereon. The AEAPS monolayer samples having no ruthenium adsorbed thereon are electrochemically inactive.

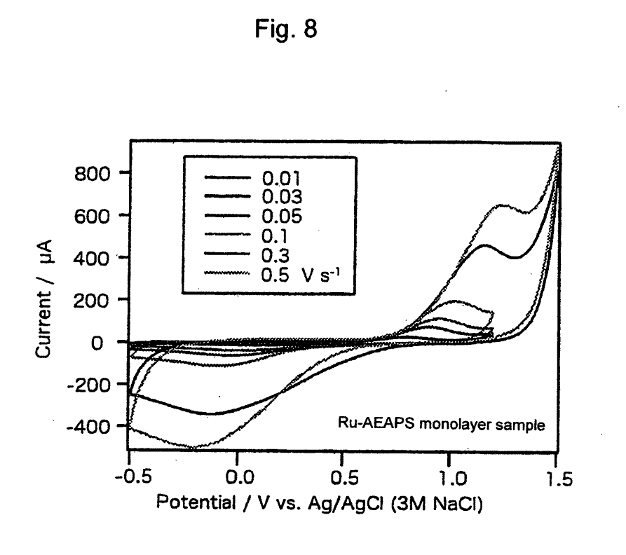

FIG. 8 shows the cyclic voltammogram (CV) of the AEAPS monolayer samples having ruthenium adsorbed thereon. The AEAPS monolayer samples having ruthenium adsorbed thereon clearly exhibited electrochemical responses. A positive current is an oxidation current and a negative current is a reduction current. The oxidation and reduction peaks appeared at the electric potentials of 0.8 V or higher and 0 V or lower, respectively. The oxidation wave peak was observed at a position very far away from the reduction wave peak. This can be explained as follows. If the ruthenium complex is assumed to be formed, an insulator silicon oxide and a carbon chain are present between the substrate and the ruthenium ions, and overvoltage is required for electric current.

Based on the current values shown in FIG. 8, the number of ruthenium ions adsorbed on the substrate surface was determined. The number of ions adsorbed on the surface was 2.1×10¹⁵ ions/cm². When a film was formed on a silicon oxide substrate via silane coupling, the molecular density was about 1.0×10¹⁵ molecules/cm². The amount of ruthenium adsorbed in this example was of the same order as the one measured above. Since the current curve is considerably irregular and the estimate based on the current value could be considerably erroneous, it can be said that the number of ruthenium ions adsorbed on the substrate surface is sufficiently consistent with the molecular density of the silane coupling agent.

### [Redox-Type Molecular Memory Device]

The organic thin film of the present invention is electrochemically active and can repeat the procedure of retaining and releasing electric charges in accordance with the electrode potential many times. When a silicon surface is coated with a self-assembled monolayer (SAM) comprising electrochemically active molecules, the functions of recording and deleting electric charges can be imparted to silicon. Thus, silicon can be utilized as an element for a solid memory device. Molecular redox is equivalent to the procedure of electron release from molecules and electron injection into molecules. The term “oxidation” refers to the accumulation of positive charges and the term “reduction” refers to the accumulation of negative charges.

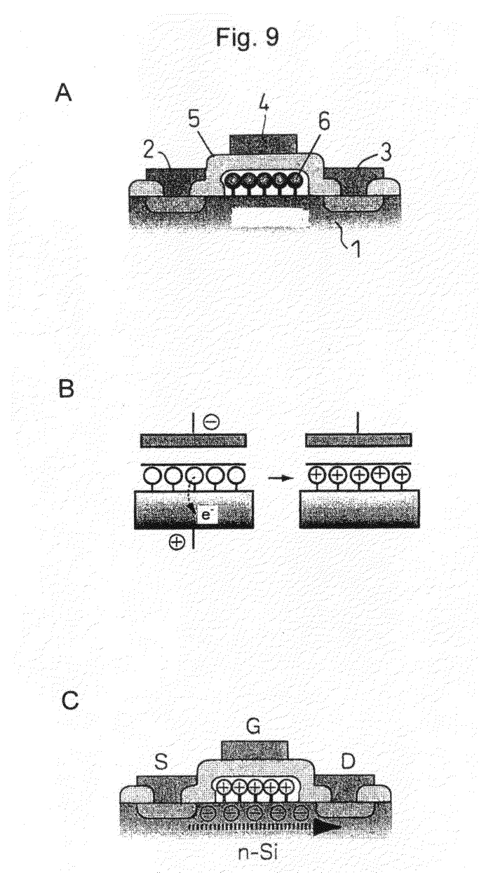

FIG. 9A-9C shows an example of a structure of a device when redox performance of the organic thin film of the present invention is utilized for a memory device. FIG. 9A shows an example of a structure of a redox-type molecular memory device. A gate electrode 4 is provided on a silicon substrate 1 while sandwiching the source 2 and the drain 3. Under the gate electrode 4, the organic thin film 6 of the present invention is bound to a silicon substrate 1 while being surrounded by an insulator 5. FIG. 9B shows charge accumulation on a redox-type molecular memory device. FIG. 9C shows the performance of FET after charge accumulation.

In the case shown in FIG. 9A-9C, a redox-type monolayer is introduced at the interface of the gate oxide film and the silicon substrate of common MOS-FET. A redox molecule that remains neutral under reduction conditions and becomes a positive ion under oxidation conditions is exemplified herein. Application of a negative potential exceeding the threshold to the gate (G) causes the electron migration from the molecules to the silicon substrate (due to electrochemical oxidation of molecules) and conversion of molecules into positive ions (i.e., accumulation of positive charges on a monolayer). In contrast, application of a positive gate voltage results in reduction of molecules and elimination of accumulated charges. If the energy barrier at the molecule-silicon conjugate site is adequately regulated, molecules remain oxidized (positively charged) even if the application of the gate voltage is terminated. The accumulated positive charges open the channel at the n-Si substrate/molecule layer interface, and a current flows between the source (S) and the drain (D). In contrast, a current does not flow under reduction conditions. This memory device is capable of reading the accumulation state of charges in a nondestructive manner based on the presence of a current between the source (S) and the drain (D).

### [Molecular Transistor Device]

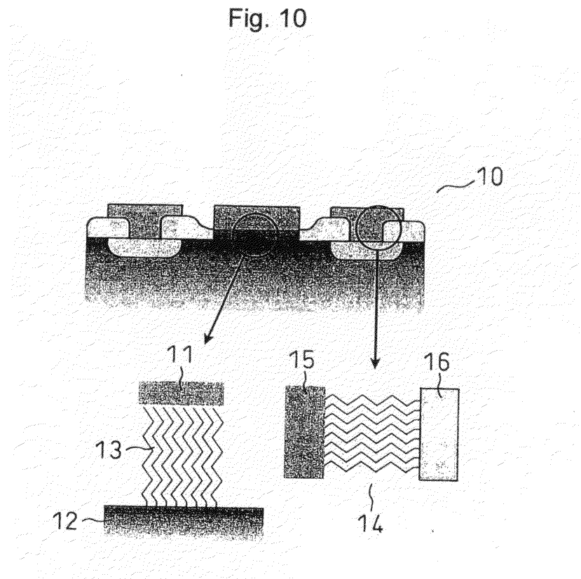

FIG. 10 shows an application example of redox performance of the organic thin film of the present invention to a molecular transistor device utilized as a means for regulating electron migration between a source charge and a drain electrode. The electrode portion of Si-FET 10 is composed of the electrode 11, the Si substrate 12, and the organic thin film 13 of the present invention bound thereto as an insulator. As a diffusion barrier 14 of the source and the drain, the organic thin film of the present invention is bound to the Cu/SiO₂ interface.

When a solid substrate is coated with the organic self-assembled monolayer (SAM) of the present invention, the surface of the substrate is densely coated with given well-oriented organic molecules. This can induce remarkable changes in various surface properties of the substrate. The same applies to electronic properties. If an organic silane monolayer is inserted at the interface of the gate oxide film and the organic semiconductor thin film, for example, the conditions of the interface of the gate oxide film and the organic semiconductor thin film are modified, and organic transistor properties, such as the onset voltage or gain, are also changed.

### [Electrochemical Sensor]

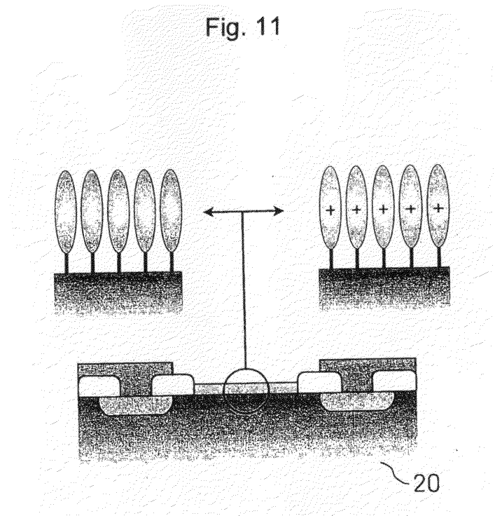

FIG. 11 shows an application example of redox performance of the organic thin film of the present invention to an electrochemical sensor 20 utilized as a means for detecting electron migration between an electrode and a substance to be detected.

### INDUSTRIAL APPLICABILITY

The organic thin film of the present invention enables preparation of various devices utilizing organic molecules as operating units, such as a molecular memory device, a molecular transistor device, an electrochemical sensor, and a dye-sensitized solar cell.

1. An electrochemically active organic thin film comprising: a substrate; an organic molecular film comprising organic molecules having terminal amino groups chemically fixed on the surface of the substrate; and metal atoms or metal ions coordinately bound to the amino groups.

2. The electrochemically active organic thin film according to claim 1, wherein the organic molecular film is a self-assembled monolayer (SAM).

3. The electrochemically active organic thin film according to claim 1, wherein the organic molecules having terminal amino functional groups are aminosilane compounds.

4. The electrochemically active organic thin film according to claim 3, wherein the aminosilane compounds are aminoethylaminopropyltrimethoxysilane or aminoethylaminopropyltriethoxysilane.

5. The electrochemically active organic thin film according to claim 1, wherein the substrate is a member selected from among a metal oxide substrate, a metal substrate coated with an oxide film, a metal substrate, and a semiconductor substrate.

6. The electrochemically active organic thin film according to claim 5, wherein the substrate comprises at least one member selected from among silicon, titanium oxide, tin oxide, and indium-tin oxide.

7. The electrochemically active organic thin film according to claim 1, wherein the metal atoms or metal ions are transition metals or transition metal ions.

8. The electrochemically active organic thin film according to claim 7, wherein the transition metal ions are ruthenium ions.

9. The electrochemically active organic thin film according to claim 1, which is an organic multilayer thin film comprising: a substrate; a layer of organic molecules having terminal amino functional groups chemically fixed on the surface of the substrate; metal atoms or metal ions coordinately bound to the terminal amino functional groups as ligands to form complexes; and a layer of organic molecules having terminal amino functional groups as ligands coordinately bound to the metal atoms or metal ions.

10. A method for producing an electrochemically active organic thin film comprising at least a step of chemically fixing organic molecules having terminal amino functional groups on a substrate surface and a step of forming complexes by coordinating metal atoms or metal ions to terminal amino functional groups as ligands.

11. The method for producing an electrochemically active organic thin film according to claim 10, wherein the step of chemically fixing organic molecules having terminal amino functional groups on the substrate surface is a step of forming a self-assembled monolayer (SAM).

12. The method for producing an electrochemically active organic thin film according to claim 11, wherein the step of forming a self-assembled monolayer (SAM) is a gas-phase process whereby the organic molecules having terminal amino functional groups are vapor deposited on the substrate surface.

13. The method for producing an electrochemically active organic thin film according to claim 10, wherein the organic molecules having terminal amino functional groups are aminosilane compounds.

14. The method for producing an electrochemically active organic thin film according to claim 13, wherein the aminosilane compounds are aminoethylaminopropyltrimethoxysilane or aminoethylaminopropyltriethoxysilane.

15. The method for producing an electrochemically active organic thin film according to claim 10, wherein the substrate is a member selected from among a metal oxide substrate, a metal substrate coated with an oxide film, a metal substrate, and a semiconductor substrate.

16. The method for producing an electrochemically active organic thin film according to claim 15, wherein the substrate comprises at least one member selected from among silicon, titanium oxide, tin oxide, and indium-tin oxide.

17. The method for producing an electrochemically active organic thin film according to claim 10, wherein the metal atoms or metal ions are transition metals or transition metal ions.

18. The method for producing an electrochemically active organic thin film according to claim 17, wherein the transition metal ions are ruthenium ions.

19. The method for producing an electrochemically active organic thin film according to claim 10, which further comprises a step of laminating a ligand layer of the terminal amino functional groups of the organic molecules on the metal atoms or metal ions.

20. A molecular memory device utilizing the oxidation/reduction capacity of the organic thin film according to claim 1 as a means for retaining and releasing electric charges.

21. A molecular transistor device utilizing the oxidation/reduction capacity of the organic thin film according to claim 1 as a means for regulating electron migration between a source charge and a drain electrode.

22. An electrochemical sensor utilizing the oxidation/reduction capacity of the organic thin film according to claim 1 as a means for detecting electron migration between an electrode and a substance to be detected.

23. A dye-sensitized solar cell utilizing the oxidation/reduction capacity of the organic thin film according to claim 1 as a dye.
